(19) United States
(12) Patent Application Publication
(10) Pub. No.: US 2009/0168297 A1
(43) Pub. Date: Jul. 2, 2009

(54) SEMICONDUCTOR DEVICE AND METHOD FOR MANUFACTURING THE SAME

(76) Inventor: Taek-Seung Yang, Yeoju-gun (KR)

Correspondence Address: SHERR & VAUGHN, PLLC, 620 HERNDON PARKWAY, SUITE 200, HERNDON, VA, 20170, US

(21) Appl. No.: 12/344,435

(22) Filed: Dec. 26, 2008

(30) Foreign Application Priority Data
Dec. 27, 2007 (KR) 10-2007-0138463

(51) Int. Cl. H01G 4/008; B05D 5/12; C23C 16/513

(52) U.S. Cl. 361/305; 427/79; 427/576; 361/313

(57) ABSTRACT

Embodiments relate to a semiconductor device and a method for manufacturing the same. According to embodiments, a method may include forming a multilayer dielectric film on and/or over a lower metal line and forming an upper metal layer on and/or over the multilayer dielectric film. A semiconductor device fabricated by the method may include a lower metal line, a multilayer dielectric film including a plurality of layers laminated in this order on and/or over the lower metal line, and an upper metal layer arranged on and/or over the multilayer dielectric film. Accordingly, a semiconductor device may achieve a high-capacitance (i.e. not less than 6 fF/um²) capacitor that may be useful for non-memory products, e.g., logic products. In addition, the capacitor may have a high capacitance, and may exhibit superior durability and reliability due to good leakage current and breakdown voltage properties.

The present application claims priority under 35 U.S.C. 119 to Korean Patent Application No. 10-2007-0138463 (filed on Dec. 27, 2007), which is hereby incorporated by reference in its entirety.

### BACKGROUND

A capacitor may be an essential component of analog semiconductor devices. A capacitor may be used as a memory to store predetermined data in memory devices, such as dynamic random access memories (DRAMs). A capacitor may have a structure in which a dielectric film may be interposed between electrodes, i.e., a storage node and a plate node. As semiconductor devices have become more highly integrated, an area of memory cells constituting the memory devices may be reduced and an operating voltage may be decreased. Accordingly, an area for a capacitor for a memory device may be reduced. In spite of the reduced area, a capacitor may need to obtain a predetermined amount of electric charge required to operate the memory device. If an electric charge is insufficient, various problems, such as soft errors and shortened refresh time, may occur.

A relation between parameters determining an electric charge amount Q may be represented by the following Equation: Q=C×V. As can be seen from this Equation, an operating voltage V applied to a capacitor and a capacitance C may determine an electric charge Q. As an operating voltage of a semiconductor device may become lower while the device may become more highly integrated, one method to accumulate an electric charge above a predetermined level may be to increase the capacitance C. Accordingly, sufficient capacitance may need to be secured even in a small area. The capacitance (C) may be represented by the following Equation I:

C=ε*S/d (I)

In Equation I, C may be a capacitance, ε may be the dielectric constant of a dielectric, S may be a cross-sectional area of an electrode plate, and d may be a distance between electrode plates. As can be seen from Equation I, a capacitance may be in direct proportion to a dielectric constant and an area of the capacitor. Capacitance may also be in inverse proportion to a thickness of a dielectric film. A capacitance of a capacitor may be in direct proportion to a surface area of an electrode and a dielectric constant of the dielectric film, but may be in inverse proportion to a distance between the electrodes.

Accordingly, to achieve high-capacitance capacitors, it may be necessary to widen an electrode surface area, to use a dielectric film with a high dielectric constant, or to minimize a distance between electrodes, i.e., to make a thickness of a dielectric film as thin as possible. However, since a large electrode surface area may not be obtained through controlling device design and due to inherent characteristics of high-dielectric materials, reducing a distance between electrodes may generally be used to increase a capacitance of capacitors. Because of a high level of integration and high-performance of semiconductor devices, a variety of properties may be required for semiconductor devices. Accordingly, metal electrodes of a capacitor may be used for a capacitor electrode and metal-insulator-metal (MIM) structure capacitors may be used.

Depending on a structure and a kind of material used, metal-oxide-silicon (MOS) capacitors or silicon-insulator-silicon (SIS) capacitors, etc. may be used. In these cases, however, single crystalline or polycrystalline silicon may be used for one side of the electrode material. This may limit reduction in capacitor electrode resistance due to characteristics of the silicon. In addition, if a bias voltage is applied to a single crystalline or polycrystalline silicon electrode, the capacitor may fail to perform its function due to occurrence of depletion regions and insufficient voltage. For this reason, MIM structure capacitors, which may have a low frequency-dependency and a low variation rate according to voltage and temperature, may be used.

FIGS. 1A and 1B are cross-sectional views illustrating examples of a MIM structure semiconductor device according to the related art. FIG. 1A illustrates a structure of a semiconductor device capacitor using copper (Cu) for a metal line, which may be applicable to a back end of line (BEOL) process. FIG. 1B illustrates a structure of a semiconductor device capacitor using aluminum (Al) as a metal line, which may be applicable to a BEOL process.

Referring to FIG. 1A, a MIM structure may be arranged on and/or over a lower structure, such as metal line 10. MIM structure may include lower metal layer 11, thin film layer 12 made of silicon nitride (SiN), and upper metal layer 13. Metal line 14 may be arranged on and/or over MIM structure. Each of metal lines 10 and 14 may be made of copper (Cu).

Referring to FIG. 1B, if a lower structure such as metal line 20 is arranged, the MIM structure may include metal line 20 of aluminum, lower metal layer 21 made of silicon nitride (SiN), and upper metal layer 22. Thin film layers 12 and 21 shown in FIGS. 1A and 1B may have a thickness of about 340 Å and may have a capacitance is about 2 fF/um² with this thickness. Thin film layers 12 and 21 may be reduced in thickness to realize a high-capacitance capacitor.

However, a MIM structure may entail difficulty in reducing a thickness of dielectric thin film layers 12 and 21. That is, film uniformity of the thin film layers may be difficult to control when the thin film layers 12 and 21 made of silicon nitride (SiN) have a thickness not more than 300 Å. Accordingly, in an etching process, the metal layer may be exposed in a local portion where the MIM structure has a lower thickness. As a result, reduction in a thickness of thin film layers for the purpose of increasing capacitor capacitance may be limited. Logic and CMOS image sensor products, which may be currently fabricated with 130 nm technologies, may employ a method of reducing only a thickness of a dielectric thin film, i.e., silicon nitride, to secure capacitance not more than 2 fF/um².

As mentioned above, however, this method may not adjust a thickness of dielectric thin films to a level not more than 300 Å, and thus, may not secure a capacitance not less than 4 fF/um². It may therefore be important to obtain a high capacitance by using a high-dielectric material (high k material) as dielectric thin films. However, there may not be yet a specific suggestion associated with a kind of material and MIM structure used to obtain an optimal high-capacitance.

### SUMMARY

Embodiments relate to a semiconductor device and a method for manufacturing the same that provides a high-capacitance MIM structure capacitor.

Embodiments relate to a semiconductor device and a method for manufacturing the same that provides a high-capacitance capacitor for non-memory products by using a high dielectric material, without reducing a thickness of a dielectric thin film.

Embodiments relate to a semiconductor device and a method for manufacturing the same that provides a high-capacitance (for example, not less than 6 fF/um²) capacitor for logic products, without reducing a thickness of a dielectric thin film.

According to embodiments, a semiconductor device may include at least one of the following. A lower metal line. A multilayer dielectric film including a plurality of layers laminated on and/or over the lower metal line. An upper metal layer on and/or over the multilayer dielectric film. According to embodiments, a semiconductor device may include a lower metal layer arranged under and/or below the multilayer dielectric film. According to embodiments, the multilayer dielectric film may be formed by depositing at least one of a hafnium (Hf) based-oxide film and an aluminum (Al)-based oxide film.

According to embodiments, the multilayer dielectric film may include at least one of the following. A first oxide film based on aluminum (Al). A second oxide film based on hafnium (Hf) on and/or over the first oxide film. A third oxide film based on aluminum (Al) on and/or over the second oxide film. The first and third oxide films may be made of aluminum oxide (Al2O3), and the second oxide film may be made of hafnium dioxide (HfO2).

According to embodiments, a method for fabricating a semiconductor device may include at least one of the following. Forming a multilayer dielectric film on and/or over a lower metal line. Forming an upper metal layer on and/or over the multilayer dielectric film. According to embodiments, forming the multilayer dielectric film may be performed by sequentially depositing a plurality of high dielectric materials on and/or over the lower metal line through atomic layer deposition. According to embodiments, forming the multilayer dielectric film may be performed by sequentially depositing at least one of a hafnium (Hf) based-oxide film and an aluminum (Al)-based oxide film through atomic layer deposition.

According to embodiments, forming the multilayer dielectric film may be performed by forming the multilayer dielectric film through atomic layer deposition, where the formation of the multilayer dielectric film may be carried out by sequentially forming a first oxide film based on aluminum (Al), a second oxide film based on hafnium (Hf) on and/or over the first oxide film, and a third oxide film based on aluminum (Al) on and/or over the second oxide film. According to embodiments, the atomic layer deposition may be performed using ozone (O3) plasma as a reaction gas.

According to embodiments, first and third oxide films may be formed using aluminum oxide (Al2O3), and the second oxide film may be formed using hafnium dioxide (HfO2). Tetrakis [ethylmethylamino] hafnium (TEMAHf) and trimethyl aluminum (TMA) may be used as precursors of HfO2 and Al2O3, respectively. According to embodiments, a lower metal layer may be formed on and/or over the lower metal line prior to forming the multilayer dielectric film.

### DRAWINGS

FIGS. 1A and 1B are cross-sectional views illustrating examples of a semiconductor device MIM structure according to the related art.

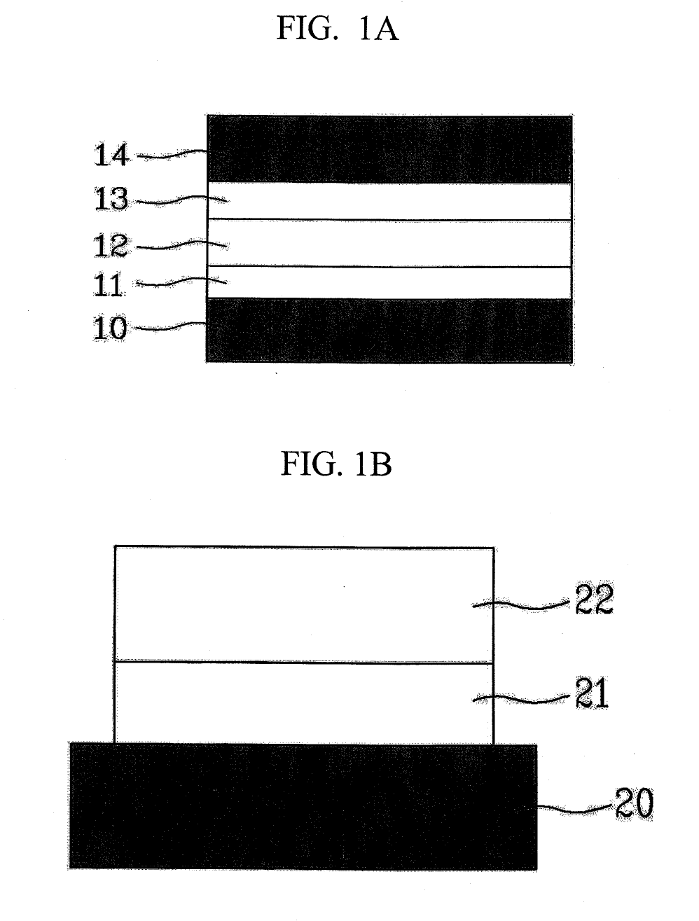

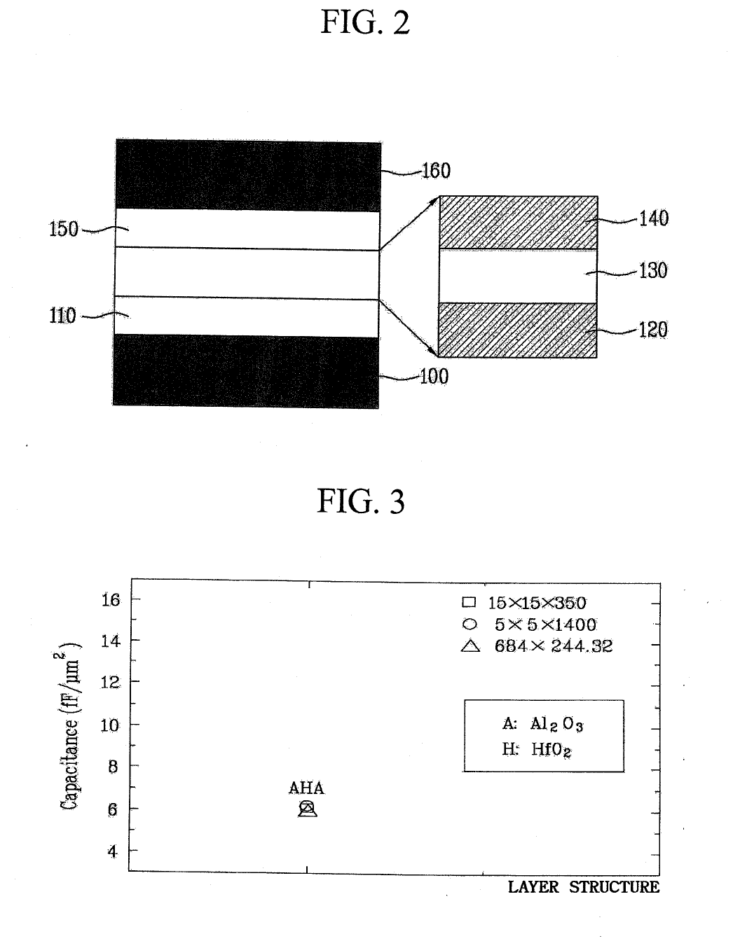

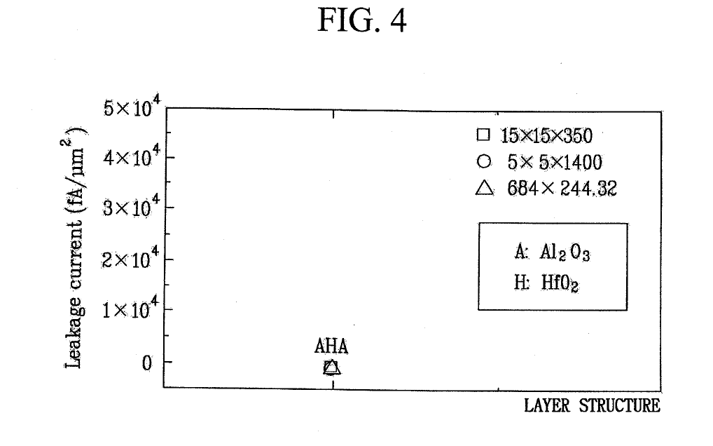

Example FIG. 2 is a cross-sectional view showing a MIM structure and describing a process for fabricating a semiconductor device according to embodiments.

Example FIGS. 3 and 4 are views showing capacitance and leakage current properties of a MIM structure according to embodiments.

### DESCRIPTION

In accordance with embodiments, a high dielectric material such as hafnium dioxide (HfO₂) or aluminum oxide (Al₂O₃) may be deposited though atomic layer deposition (ALD). This may provide a multilayer high dielectric film between metal layers. The formation of the multilayer dielectric film between metal layers may allow for production of a MIM capacitor. According to embodiments, a MIM structure may provide a relatively high capacitance of not less than 6 fF/um².

Example FIG. 2 is a cross-sectional view showing a MIM structure and describing a process for fabricating a semiconductor device according to embodiments. Referring to example FIG. 2, a MIM according to embodiments may include lower metal line 100 and multilayer dielectric film including a plurality of layers 120, 130, and 140 (also, referred to simply as a “multilayer dielectric film”). Plurality of layers 120, 130, and 140 may be laminated in this order on and/or over lower metal line 100, and upper metal layer 150 may be laminated on and/or over the multilayer dielectric film. Such a configuration may provide a semiconductor device capacitor that may use a metal line made of aluminum (Al) and may be applicable to BEOL processes. According to embodiments, lower metal line 100 may be made of aluminum (Al).

Alternatively, referring to example FIG. 2, a capacitor may use a metal line made of copper (Cu), while being applicable to BEOL processes. According to embodiments, a MIM may include lower metal line 100, lower metal layer 110 laminated on and/or over lower metal line 100, and a dielectric film, that may include a plurality of layers 120, 130, and 140. Plurality of layers may be laminated in this order on and/or over lower metal layer 110, and upper metal layer 150 may be laminated on and/or over the multilayer dielectric film 120, 130, and 140. According to embodiments, the MIM may also include lower metal layer 110 arranged under and/or below multilayer dielectric film 120, 130, and 140. In addition to lower metal layer 110 that may be formed under and/or below multilayer dielectric film 120, 130, and 140, a MIM may include lower metal layer 110, multilayer dielectric film 120, 130, and 140, and upper metal layer 150. A MIM structure 110 to 150 may use copper (Cu) for a lower metal line 100, and may include upper metal line 160 made of copper arranged on and/or over upper metal layer 150. Multilayer dielectric film 120, 130, and 140 may be a laminate in the form of a bilayer, a trilayer, or four or more layers, and may be obtained by laminating at least one of a hafnium (Hf) based-oxide film and an aluminum (Al)-based oxide film.

As shown in FIG. 2, multilayer dielectric film 120, 130, and 140 may have a trilayer structure, which may be formed by sequentially depositing first oxide film 120 based on aluminum (Al), second oxide film 130 based on hafnium (Hf) on and/or over first oxide film 120, and third oxide film 140 based on aluminum (Al) on and/or over second oxide film 130. According to embodiments, first and third oxide films 120 and 140 may be formed of aluminum oxide (Al₂O₃) and may have a dielectric constant ε of 9. Second oxide film 130, which may be an intermediate layer, may be formed of hafnium dioxide (HfO₂), and may have a dielectric constant ε of 20. According to embodiments, an Al₂O_{2\3}/HfO₂/Al₂O₃ multilayer dielectric film 120, 130, and 140 may be formed in a dielectric portion of a MIM structure.

Next, a process for forming a MIM structure according to embodiments will be described. For purposes of example, a process of fabricating a semiconductor device capacitor using copper (Cu) for a metal line, while being applicable to BEOL processes, will be described. According to embodiments, a process may include forming lower metal layer 110 between a lower metal line 100 and forming multilayer dielectric film 120, 130, and 140. According to embodiments, when fabricating a semiconductor device capacitor that uses aluminum (Al) for a metal line, while being applicable to BEOL processes, prior to forming multilayer dielectric film 120, 130, and 140, lower metal layer 110 that may be formed on and/or over lower metal line 100 may be excluded.

Referring to example FIG. 2, lower metal line 100 may be formed on and/or over a semiconductor substrate. Lower metal layer 110 may be formed on and/or over lower metal line 100. Multilayer dielectric film including a plurality of layers 120, 130, and 140 may be thinly formed on and/or over lower metal layer 110, for example through an ALD process. During the ALD process, ozone (O3) plasma may be used as a reaction gas. A plurality of layers 120, 130, and 140 may be sequentially thinly laminated on and/or over lower metal layer 110. According to embodiments, the laminated multilayer dielectric film 120, 130, and 140 may include at least one of a hafnium (Hf)-based oxide film and an aluminum (Al)-based oxide film.

A process for forming multilayer dielectric film 120, 130, and 140 according to embodiments may include forming first oxide film 120 composed of aluminum (Al) may be on and/or over lower metal layer 110. Second oxide film 130 composed of hafnium (Hf) may be formed on and/or over first oxide film 120. Third oxide film 140 composed of aluminum (Al) may be formed on and/or over second oxide film 130. First oxide film 120 may be made of aluminum oxide (Al₂O₃), second oxide film 130 may be made of hafnium dioxide (HfO₂), and the third oxide film 140 may be made of aluminum oxide (Al₂O₃). According to embodiments, the multilayer dielectric film may have a structure in which second oxide film 130 may be sandwiched between first and third oxide films 120 and 140, which may be made of the same oxide. Hafnium dioxide (HfO₂) and aluminum oxide (Al₂O₃) may be used as materials for multilayer dielectric film 120, 130, and 140. Tetrakis[ethylmethylamino] hafnium (TEMAHf) and trimethyl aluminum (TMA) may be used as precursors of HfO₂ and A₂2O₃, respectively. Upper metal layer 150 may be formed on and/or over multilayer dielectric film 120, 130, and 140 and an upper metal line 160 may be formed on and/or over upper metal layer 150.

In an ALD process to form a MIM structure according to embodiments, a thin film may have a thickness not more than approximately 100 Å and a good uniformity not exceeding 2% variation in the thickness.

Example FIG. 3 is a view showing capacitance of a MIM structure according to embodiments. Example FIG. 4 is a view showing leakage current properties of a MIM structure according to embodiments. In AHA shown in example FIGS. 3 and 4, A (Al₂O₃) may have a thickness of approximately 45 Å to 55 Å, H (HfO₂) may have a thickness of approximately 90 Å to 110 Å, and A (Al2O3) may have a thickness of approximately 45 Å to 55 Å. In addition, capacitance can be measured by various methods. Symbols □, Δ, and o may represent data results measured by any method. According to embodiments, □ may represent data measured at 15 um×15 um×350 ea. According to embodiments, 15 um×15 um may indicate an area of each metal layer and 350 ea. may indicate a number of capacitors. A may represent data measured at 5 um×5 um×1400 ea. According to embodiments, 5 um×5 um may indicate an area of each metal layer and 1400 ea. may indicate a number of capacitors. o may represent data measured at 648 um×244.32 um×1 ea. According to embodiments, 648 um×244.32 um may indicate an area of each metal layer and 1 ea. may indicate a number of capacitors.

According to embodiments, a MIM structure, as shown in example FIG. 3, may realize a capacitor with a relatively high capacitance of 6±0.5 fA/um². As shown in example FIG. 4, a MIM may exhibit a low leakage current not more than 10 fA/um². A MIM capacitor with a high-capacitance may be obtained by using hafnium dioxide (HfO₂) and aluminum oxide (Al₂O₃) as high dielectric materials, while being based on a MIM structure, without reducing a thickness of a dielectric thin film. A dielectric thin film may be formed of a multilayer high-dielectric, which may secure a relatively high-capacitance (for example, not less than 6 fF/um²) capacitor that may be useful for non-memory products, e.g., logic products. An MIM capacitor according to embodiments may secure a high capacitance, and may exhibit superior durability and reliability due to good leakage current and breakdown voltage properties, and may therefore be usable for a standard MIM structure device.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a lower metal line;
a multilayer dielectric film including a plurality of layers over the lower metal line; and
an upper metal layer over the multilayer dielectric film.

2. The device of claim 1, wherein the lower metal line comprises aluminum (Al).

3. The device of claim 1, further comprising a lower metal layer over the lower metal line and under the multilayer dielectric film.

4. The device of claim 3, wherein the lower metal line comprises copper (Cu).

5. The device of claim 4, further comprising an upper metal line over the upper metal layer, wherein the upper metal line comprises copper (Cu).

6. The device of claim 1, wherein the multilayer dielectric film compromises a first oxide film based on aluminum (Al), a second oxide film based on hafnium (Hf) over the first oxide film, and a third oxide film based on aluminum (Al) over the second oxide film.

7. The device of claim 6, wherein the first and third oxide films each comprise aluminum oxide (Al2O3), and the second oxide film comprises hafnium dioxide (HfO2).

8. The device of claim 7, wherein the first and third oxide films each have a thickness of approximately 45 Å to 55 Å, and the second oxide film has a thickness of approximately 90 Å to 110 Å.

9. A method comprising:
forming a multilayer dielectric film over a lower metal line; and
forming an upper metal layer over the multilayer dielectric film.

10. The method of claim 9, wherein the lower metal line comprises aluminum (Al), and wherein the multilayer dielectric film compromises at least one of a hafnium (Hf) based-oxide film and an aluminum (Al)-based oxide film.

11. The method of claim 9, wherein forming the multilayer dielectric film comprises sequentially depositing a plurality of high dielectric materials over the lower metal line through atomic layer deposition.

12. The method of claim 11, wherein the atomic layer deposition is performed using ozone (O3) plasma as a reaction gas.

13. The method of claim 9, wherein forming the multilayer dielectric film comprises sequentially depositing at least one of a hafnium (Hf) based-oxide film and an aluminum (Al)-based oxide film through atomic layer deposition.

14. The method of claim 9, wherein forming the multilayer dielectric film compromises forming the multilayer dielectric film through atomic layer deposition.

15. The method of claim 14, wherein forming the multilayer dielectric film comprises sequentially forming a first aluminum (Al) based oxide film, a second hafnium (Hf) based oxide film over the first oxide film, and a third aluminum (Al) based oxide film over the second oxide film.

16. The method of claim 15, wherein the first and third oxide films each comprise aluminum oxide (Al2O3), and the second oxide film comprises hafnium dioxide (HfO2).

17. The method of claim 16, wherein the first and third oxide films each have a thickness of approximately 45 Å to 55 Å, and the second oxide film has a thickness of approximately 90 Å to 110 Å.

18. The method of claim 9, further comprising forming a lower metal layer over the lower metal line prior to forming the multilayer dielectric film.

19. The method of claim 18, wherein the lower metal line comprises copper (Cu) and the multilayer dielectric film comprises at least one of a hafnium (Hf) based-oxide film and an aluminum (Al)-based oxide film.

20. The method of claim 19, further comprising forming an upper metal line over the upper metal layer, wherein the upper metal line comprises copper (Cu).
